(19) United States
(12) Patent Application Publication
(10) Pub. No.: US 2018/0107075 A1
(43) Pub. Date: Apr. 19, 2018

(54) ARRAY SUBSTRATE PIXEL CONNECTION STRUCTURE AND ARRAY SUBSTRATE

(71) Applicant: Penggang CHANG, Shenzhen, Guangdong (CN)

(72) Inventor: Penggang CHANG, Shenzhen, Guangdong (CN)

(73) Assignee: Shenzhen China Star Optoelectronics Technology Co., Ltd., Shenzhen, Guangdong (CN)

(21) Appl. No.: 15/327,771

(22) PCT Filed: Dec. 22, 2016
(86) PCT No.: PCT/CN2016/111461

§ 371 Date: Jan. 20, 2017

(30) Foreign Application Priority Data
Oct. 17, 2016 (CN) 201610902876.4

(51) Int. Cl. G02F 1/1343; G02F 1/1362; G09G 3/36; H01L 27/12

(52) U.S. Cl. CPC G02F 1/134309; G02F 1/136286; G09G 3/3648; G09G 2320/0219; G09G 2300/0823; G09G 2300/0434; H01L 27/1214

(57) ABSTRACT

Provided is an array substrate pixel connection structure, including data lines, being aligned side by side along a first direction; gate lines being aligned side by side along a second direction; the data lines and the gate lines crisscrossing to define sub pixels, and the sub pixels including a first row to a fourth row of sub pixels which are aligned in order along the second direction, the sub pixels in the first, the second row of sub pixels being coupled to the data line which is adjacent, and the sub pixels in the third, the fourth row of sub pixels being coupled to the data line which is adjacent, and the data line which the third, the fourth rows of sub pixels are coupled and the data line which the first, the second rows of sub pixels are coupled have two alignment directions which are opposite.

### CROSS REFERENCE

This application claims the priority of Chinese Patent Application No. 201610902876.4, entitled “Array substrate pixel connection structure and array substrate”, filed on Oct. 17, 2016, the disclosure of which is incorporated herein by reference in its entirety.

### FIELD OF THE INVENTION

The present invention relates to a liquid crystal display manufacture technology field, and more particularly to an array substrate pixel connection structure and an array substrate.

### BACKGROUND OF THE INVENTION

The Liquid Crystal Display (LCD) has been widely applied in all aspects of our lives. From the cell phone, the video recorder, the digital camera, the notebook of the middle side, the laptop computer, the large scale home television to the large projection equipment, the thin film transistor LCD ensures its champion in the display market with the basis of the light, thin advantages plus the perfect image and the fast response property.

The array substrate pixel connection structure is one core part of the thin film transistor LCD. The array substrate pixel connection structure directly influences aperture ratio, the response speed, the display image quality of the liquid crystal display. At present, the research for the pixel structure of the liquid crystal display has already been mature but still, there is some remaining to be improved.

The drive of the liquid crystal display must have the polarity inversion. The electrical field applied to the liquid crystal molecules is directional. In the different time, applying the electric field of opposite direction to the liquid crystal is so called the polarity inversion. The polarity inversion is to avoid the residual direct current of the liquid crystal. The common pixel array polarity inversions have four types, the frame inversion, the column inversion, the row inversion and the dot inversion. The effect of dot inversion in space can be achieved on the basis of the column inversion, and the issue that the temperature is too high because the frequently polarity change as driving will not occur, and it has been widely used in the panel industry. However, the liquid crystal inversion according to prior art only can realize the 2D effect if the exquisite image is required and the resolution has to be ensured. The 3D application cannot be directly achieved.

### SUMMARY OF THE INVENTION

An objective of the present invention is to provide an array substrate pixel connection structure capable of realizing 2D and 3D effects of the liquid crystal panel.

For realizing the aforesaid objective, the technical solution provided by the embodiments of the present invention is:

The array substrate pixel connection structure comprises a plurality of data lines, and the plurality of data lines being aligned side by side along a first direction; a plurality of gate lines, and the plurality of gate lines being aligned side by side along a second direction; the plurality of data lines and the plurality of gate lines crisscrossing to one another to define a plurality of sub pixels, and the plurality of sub pixels being aligned in array, and each of the sub pixels comprising a thin film transistor and a pixel electrode, and the plurality of sub pixels comprising a first row of sub pixels, a second row of sub pixels, a third row of sub pixels and a fourth row of sub pixels which are aligned in order along the second direction, the sub pixels in the first row of sub pixels and the second row of sub pixels being coupled to the data line which is adjacent, and the sub pixels in the third row of sub pixels and the fourth row of sub pixels being coupled to the data line which is adjacent, and the data line which the third row of sub pixels are coupled and the fourth row of sub pixels are coupled and the data line which the first row of sub pixels and the second row of sub pixels are coupled have two alignment directions which are opposite.

The plurality of sub pixels comprises a fifth row of sub pixels and a sixth row of sub pixels which are aligned in order with the fourth row of sub pixels along the second direction; the sub pixels in the fifth row of sub pixels and the sixth row of sub pixels are coupled to the data line which is adjacent and at one side opposite to the first direction.

Amounts of pixel units included in the first row of sub pixels to the sixth row of sub pixels which are consist of the sub pixels are the same.

In the first row, the second row of sub pixels, each of the sub pixels is coupled to the adjacent data line at the left side or coupled to the adjacent data line at the right side, and in the third row, the fourth row of sub pixels each of the sub pixels is coupled to the adjacent data line at the right side or coupled to the adjacent data line at the left side.

In the fifth row, the sixth row of sub pixels, each of the sub pixels is coupled to the adjacent data line at the left side or coupled to the adjacent data line at the right side.

Along the second direction, the sub pixels of the same type in the pixel units of the same column in the first row, the second row, the third row, the fourth row, the fifth row and the sixth row of sub pixels are in the same column.

The plurality of sub pixels comprises sub pixels of three different colors; the sub pixels of three different colors in each row of pixels are aligned in order in the first row, the second row, the third row, the fourth row, the fifth row and the sixth row of sub pixels.

In the first row, the second row, the third row, the fourth row, the fifth row and the sixth row of sub pixels, the sub pixels between two data lines which are adjacent in the first column are the sub pixels of the same type, and the sub pixels in the first row, the second row of sub pixels are coupled to the first data line of the two data line which are adjacent, and the sub pixels in the third row, the fourth row of sub pixels are coupled to the second data line, and the sub pixels in the fifth row, the sixth row of sub pixels are coupled to the first data line.

In the first row, the second row, the third row, the fourth row, the fifth row and the sixth row of sub pixels, the sub pixels between two data lines which are adjacent in the second column are the sub pixels of the same type, and the sub pixels in the first row, the second row of sub pixels are coupled to the data line which is close to the first column in the two data lines which are adjacent, and the sub pixels in the third row, the fourth row of sub pixels are coupled to the other data line, and the sub pixels in the fifth row, the sixth row of sub pixels are coupled to the data line which is close to the first column.

The array substrate of the present invention comprises the array substrate pixel connection structure.

The pixels of the same row in the array substrate pixel connection structure of the present application are coupled to the gate line of the same side; in the pixels of the same column, every two adjacent pixels are one pixel combination, and the adjacent pixel combinations are coupled to the different data line, and by utilizing the simultaneous charging pixel combination, the 2D effect can be realized and the 3D effect also can be achieved.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a diagram of an array substrate pixel connection structure according to the present invention.

### DETAILED DESCRIPTION OF PREFERRED EMBODIMENTS

Embodiments of the present invention are described in detail with the technical matters, structural features, achieved objects, and effects with reference to the accompanying drawings as follows. It is clear that the described embodiments are part of embodiments of the present invention, but not all embodiments. Based on the embodiments of the present invention, all other embodiments to those of ordinary skill in the premise of no creative efforts obtained, should be considered within the scope of protection of the present invention.

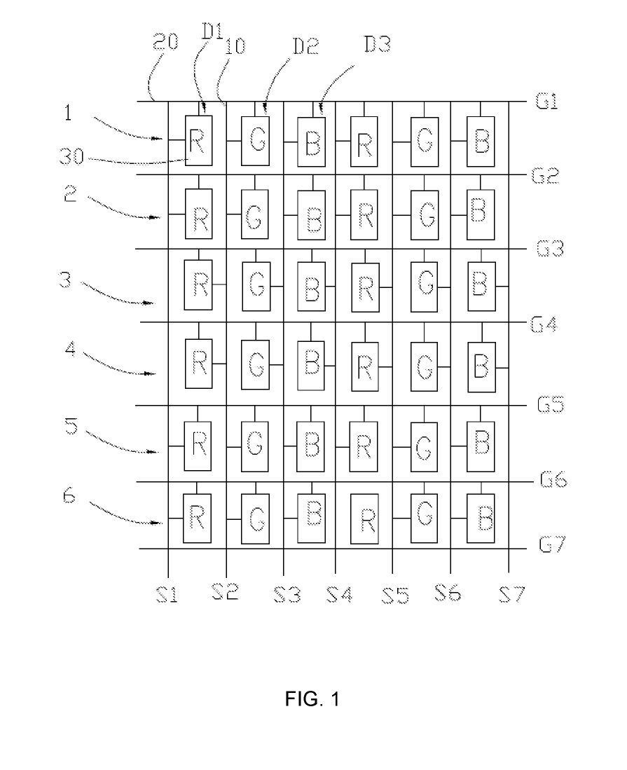

Please refer to FIG. 1. The present invention provides an array substrate and the pixel connection structure thereof. The array substrate pixel connection structure comprises a plurality of data lines 10, and the plurality of data lines 10 being aligned side by side along a first direction A; a plurality of gate lines 20, and the plurality of gate lines 20 being aligned side by side along a second direction B. The plurality of data lines 10 and the plurality of gate lines 20 crisscross to one another to define a plurality of sub pixels 30, and the plurality of sub pixels 30 are aligned in array, and each of the sub pixels comprises a thin film transistor and a pixel electrode (not shown).

The plurality of sub pixels comprises a first row 1 of sub pixels, a second row 2 of sub pixels, a third row 3 of sub pixels and a fourth row 4 of sub pixels which are aligned in order along the second direction B, and the sub pixels in the first row 1 of sub pixels and the second row 2 of sub pixels are coupled to the data line which is adjacent, and the sub pixels in the third row 3 of sub pixels and the fourth row 4 of sub pixels are coupled to the data line which is adjacent, and the data line which the third row 3 of sub pixels and the fourth row 4 of sub pixels are coupled and the data line which the first row 1 of sub pixels and the second row 2 of sub pixels are coupled have two alignment directions which are opposite. The plurality of sub pixels further comprises a fifth row 5 of sub pixels and a sixth row 6 of sub pixels which are aligned in order with the fourth row 4 of sub pixels along the second direction B; the sub pixels in the fifth row 5 of sub pixels and the sixth row 6 of sub pixels are coupled to the data line which is adjacent and at one side opposite to the first direction A. For instance, the data line which the first row 1 of sub pixels and the second row 2 of sub pixels are coupled is the data line at the left side of the two data lines which are adjacent. Then, the data line which the third row 3 of sub pixels and the fourth row 4 of sub pixels are coupled is the data line at the right side of the two data lines which are adjacent.

Furthermore, in the first row 1 of sub pixels and the second row 2 of sub pixels, each of the sub pixels is coupled to the adjacent data line at the left side or coupled to the adjacent data line at the right side, and in the third row 3 of sub pixels and the fourth row 4 of sub pixels each of the sub pixels is coupled to the adjacent data line at the right side or coupled to the adjacent data line at the left side. In the fifth row 5 of sub pixels and the sixth row 6 of sub pixels, each of the sub pixels is coupled to the adjacent data line at the left side or coupled to the adjacent data line at the right side.

Amounts of pixel units included in the first row of sub pixels to the sixth row of sub pixels, i.e. the first row 1, the second row 2, the third row 3, the fourth row 4, the fifth row 5 and the sixth row 6 of sub pixels which are consist of the sub pixels are the same. The plurality of sub pixels comprises sub pixels of three different colors; the sub pixels of three different colors in each row of pixels are aligned in order in the first row 1, the second row 2, the third row 3, the fourth row 4, the fifth row 5 and the sixth row 6 of sub pixels. In this embodiment, the sub pixels of the three different colors in each row of pixels respectively are red sub pixel R, green sub pixels G and blue sub pixels B. Each row of pixels has a plurality of pixel units aligned in order.

Furthermore, along the second direction, the sub pixels of the same type in the pixel units of the same column in the first row 1, the second row 2, the third row 3, the fourth row 4, the fifth row 5 and the sixth row 6 of sub pixels are in the same column.

In the first row 1, the second row 2, the third row 3, the fourth row 4, the fifth row 5 and the sixth row 6 of sub pixels, the sub pixels between two data lines which are adjacent in the first column are the sub pixels of the same type, and the sub pixels in the first row 1, the second row 2 of sub pixels are coupled to the first data line of the two data line which are adjacent, and the sub pixels in the third row 3, the fourth row 4 of sub pixels are coupled to the second data line, and the sub pixels in the fifth row 5, the sixth row 6 of sub pixels are coupled to the first data line.

In the first row 1, the second row 2, the third row 3, the fourth row 4, the fifth row 5 and the sixth row 6 of sub pixels, the sub pixels between two data lines which are adjacent in the second column are the sub pixels of the same type, and the sub pixels in the first row 1, the second row 2 of sub pixels are coupled to the data line which is close to the first column in the two data lines which are adjacent, and the sub pixels in the third row 3, the fourth row 4 of sub pixels are coupled to the other data line, and the sub pixels in the fifth row 5, the sixth row 6 of sub pixels are coupled to the data line which is close to the first column.

As shown in FIG. 1, the explanation and description with the specific embodiment are conducted below.

The data lines of forming the first row 1, the second row 2, the third row 3, the fourth row 4, the fifth row 5 and the sixth row 6 of sub pixels respectively are S1, S2, S3, S4, S5, S6 and S7. The gate lines are G1, G2, G3, G4, G5, G6 and G7. The sub pixels are all coupled to the gate lines above. The first direction A is a direction from the data line S1 to the data line S7. The second direction B is a direction from the gate line G1 to the gate line G7. The gate lines G1, G2 form the first row 1 of the sub pixels, and the sub pixels in the row of sub pixels are a plurality of RGB pixels which are aligned in order. The gate lines G2, G3 form the second row 2 of the sub pixels, and the sub pixels in the row of sub pixels are a plurality of RGB pixels which are aligned in order. The gate lines G3, G4 form the third row 3 of the sub pixels, and the sub pixels in the row of sub pixels are a plurality of RGB pixels which are aligned in order. The gate lines G4, G5 form the fourth row 4 of the sub pixels, and the sub pixels in the row of sub pixels are a plurality of RGB pixels which are aligned in order. The gate lines G5, G6 form the fifth row 5 of the sub pixels, and the sub pixels in the row of sub pixels are a plurality of RGB pixels which are aligned in order. The gate lines G6, G7 form the sixth row 6 of the sub pixels, and the sub pixels in the row of sub pixels are a plurality of RGB pixels which are aligned in order.

The data lines S1, S2 form the first column D1, and the sub pixels between the data lines S1, S2 are the first R sub pixels of the first row 1 of sub pixels to the sixth row 6 of sub pixels. The data lines S2, S3 form the second column D2, and the sub pixels between the data lines S1, S2 are the first G sub pixels of the first row 1 of sub pixels to the sixth row 6 of sub pixels. The data lines S3, S4 form the third column D3, and the sub pixels between the data lines S1, S2 are the first B sub pixels of the first row 1 of sub pixels to the sixth row 6 of sub pixels.

The R sub pixels of the first row 1 of sub pixels, the second row 2 of sub pixels are coupled to the data line S1 of the first column. The G sub pixels of the first row 1 of sub pixels, the second row 2 of sub pixels are coupled to S2 of the first column. The B sub pixels of the first row 1 of sub pixels, the second row 2 of sub pixels are coupled to S3 of the second column. The pixel units of the next set are still coupled in such connection order, i.e. being coupled to the data line which is opposite to the first direction. Namely, the sub pixels of the first row 1 of sub pixels, the second row 2 are coupled to the data line at the left side of the pixel column.

The R sub pixels of the third row 3 of sub pixels, the fourth row 4 of sub pixels are coupled to the data line S2 of the first column. The G sub pixels of the third row 3 of sub pixels, the fourth row 4 of sub pixels are coupled to S3 of the second column. The B sub pixels of the third row 3 of sub pixels, the fourth row 4 of sub pixels are coupled to S4 of the second column. The pixel units of the next set are still coupled in such connection order, i.e. being coupled to the data line which is aligned as the same as the first direction. Namely, the sub pixels of the third row 3 of sub pixels, the fourth row 4 are coupled to the data line at the right side of the pixel column.

The R sub pixels of the fifth row 5 of sub pixels, the sixth row 6 of sub pixels are coupled to the data line S1 of the first column. The G sub pixels of the fifth row 5 of sub pixels, the sixth row 6 of sub pixels are coupled to S2 of the first column. The B sub pixels of the fifth row 5 of sub pixels, the sixth row 6 of sub pixels are coupled to S3 of the second column. The pixel units of the next set are still coupled in such connection order, i.e. being coupled to the data line which is opposite to the first direction. Namely, the sub pixels of the fifth row 5 of sub pixels, the sixth row 6 are coupled to the data line at the left side of the pixel column.

When the drive module of the array substrate drives the pixel structure, the gate line G1, G2 light two rows at the same time, i.e. the gate lines of the first row 1 of sub pixels and the second row 2 of sub pixels. Then, S1, S4 charge the R sub pixels in the first column of the first row 1 of sub pixels and the second row 2 of sub pixels and the R sub pixels in the next pixel unit at the same time, and the red color is lighted. The gate lines G3, G4 light two rows at the same time, i.e. the gate lines G3, G4 of the first row 1 of sub pixels and the second row 2 of sub pixels. Then, S2, S5 charge the R sub pixels in the second column of the first row 1 of sub pixels and the second row 2 of sub pixels and the R sub pixels in the next pixel unit at the same time, and the red color is lighted. Accordingly, the sub pixels are alternately lighted, the sub pixels of other colors will not be mistakenly lighted to realize the 3D effect.

Above are embodiments of the present invention, which does not limit the scope of the present invention. Any modifications, equivalent replacements or improvements within the spirit and principles of the embodiment described above should be covered by the protected scope of the invention.

What is claimed is:

1. An array substrate pixel connection structure, wherein the structure comprises a plurality of data lines, and the plurality of data lines being aligned side by side along a first direction; a plurality of gate lines, and the plurality of gate lines being aligned side by side along a second direction; the plurality of data lines and the plurality of gate lines crisscrossing to one another to define a plurality of sub pixels, and the plurality of sub pixels being aligned in array, and each of the sub pixels comprising a thin film transistor and a pixel electrode, and the plurality of sub pixels comprising a first row of sub pixels, a second row of sub pixels, a third row of sub pixels and a fourth row of sub pixels which are aligned in order along the second direction, the sub pixels in the first row of sub pixels and the second row of sub pixels being coupled to the data line which is adjacent, and the sub pixels in the third row of sub pixels and the fourth row of sub pixels being coupled to the data line which is adjacent, and the data line which the third row of sub pixels and the fourth row of sub pixels are coupled and the data line which the first row of sub pixels and the second row of sub pixels are coupled have two alignment directions which are opposite.

2. The array substrate pixel connection structure according to claim 1, wherein the plurality of sub pixels comprises a fifth row of sub pixels and a sixth row of sub pixels which are aligned in order with the fourth row of sub pixels along the second direction; the sub pixels in the fifth row of sub pixels and the sixth row of sub pixels are coupled to the data line which is adjacent and at one side opposite to the first direction.

3. The array substrate pixel connection structure according to claim 2, wherein amounts of pixel units included in the first row of sub pixels to the sixth row of sub pixels which are consist of the sub pixels are the same.

4. The array substrate pixel connection structure according to claim 3, wherein in the first row, the second row of sub pixels, each of the sub pixels is coupled to the adjacent data line at the left side or coupled to the adjacent data line at the right side, and in the third row, the fourth row of sub pixels each of the sub pixels is coupled to the adjacent data line at the right side or coupled to the adjacent data line at the left side.

5. The array substrate pixel connection structure according to claim 4, wherein in the fifth row, the sixth row of sub pixels, each of the sub pixels is coupled to the adjacent data line at the left side or coupled to the adjacent data line at the right side.

6. The array substrate pixel connection structure according to claim 3, wherein along the second direction, the sub pixels of the same type in the pixel units of the same column in the first row, the second row, the third row, the fourth row, the fifth row and the sixth row of sub pixels are in the same column.

7. The array substrate pixel connection structure according to claim 6, wherein the plurality of sub pixels comprises sub pixels of three different colors; the sub pixels of three different colors in each row of pixels are aligned in order in the first row, the second row, the third row, the fourth row, the fifth row and the sixth row of sub pixels.

8. The array substrate pixel connection structure according to claim 7, wherein in the first row, the second row, the third row, the fourth row, the fifth row and the sixth row of sub pixels, the sub pixels between two data lines which are adjacent in the first column are the sub pixels of the same type, and the sub pixels in the first row, the second row of sub pixels are coupled to the first data line of the two data line which are adjacent, and the sub pixels in the third row, the fourth row of sub pixels are coupled to the second data line, and the sub pixels in the fifth row, the sixth row of sub pixels are coupled to the first data line.

9. The array substrate pixel connection structure according to claim 8, wherein in the first row, the second row, the third row, the fourth row, the fifth row and the sixth row of sub pixels, the sub pixels between two data lines which are adjacent in the second column are the sub pixels of the same type, and the sub pixels in the first row, the second row of sub pixels are coupled to the data line which is close to the first column in the two data lines which are adjacent, and the sub pixels in the third row, the fourth row of sub pixels are coupled to the other data line, and the sub pixels in the fifth row, the sixth row of sub pixels are coupled to the data line which is close to the first column.

10. An array substrate, wherein the array substrate comprises an array substrate pixel connection structure, wherein the array substrate pixel connection structure comprises a plurality of data lines, and the plurality of data lines being aligned side by side along a first direction; a plurality of gate lines, and the plurality of gate lines being aligned side by side along a second direction; the plurality of data lines and the plurality of gate lines crisscrossing to one another to define a plurality of sub pixels, and the plurality of sub pixels being aligned in array, and each of the sub pixels comprising a thin film transistor and a pixel electrode, and the plurality of sub pixels comprising a first row of sub pixels, a second row of sub pixels, a third row of sub pixels and a fourth row of sub pixels which are aligned in order along the second direction, the sub pixels in the first row of sub pixels and the second row of sub pixels being coupled to the data line which is adjacent, and the sub pixels in the third row of sub pixels and the fourth row of sub pixels being coupled to the data line which is adjacent, and the data line which the third row of sub pixels and the fourth row of sub pixels are coupled and the data line which the first row of sub pixels and the second row of sub pixels are coupled have two alignment directions which are opposite.

11. The array substrate according to claim 10, wherein the plurality of sub pixels comprises a fifth row of sub pixels and a sixth row of sub pixels which are aligned in order with the fourth row of sub pixels along the second direction; the sub pixels in the fifth row of sub pixels and the sixth row of sub pixels are coupled to the data line which is adjacent and at one side opposite to the first direction.

12. The array substrate according to claim 11, wherein amounts of pixel units included in the first row of sub pixels to the sixth row of sub pixels which are consist of the sub pixels are the same.

13. The array substrate according to claim 12, wherein in the first row, the second row of sub pixels, each of the sub pixels is coupled to the adjacent data line at the left side or coupled to the adjacent data line at the right side, and in the third row, the fourth row of sub pixels each of the sub pixels is coupled to the adjacent data line at the right side or coupled to the adjacent data line at the left side.

14. The array substrate according to claim 13, wherein in the fifth row, the sixth row of sub pixels, each of the sub pixels is coupled to the adjacent data line at the left side or coupled to the adjacent data line at the right side.

15. The array substrate according to claim 12, wherein along the second direction, the sub pixels of the same type in the pixel units of the same column in the first row, the second row, the third row, the fourth row, the fifth row and the sixth row of sub pixels are in the same column.

16. The array substrate according to claim 15, wherein the plurality of sub pixels comprises sub pixels of three different colors; the sub pixels of three different colors in each row of pixels are aligned in order in the first row, the second row, the third row, the fourth row, the fifth row and the sixth row of sub pixels.

17. The array substrate according to claim 16, wherein in the first row, the second row, the third row, the fourth row, the fifth row and the sixth row of sub pixels, the sub pixels between two data lines which are adjacent in the first column are the sub pixels of the same type, and the sub pixels in the first row, the second row of sub pixels are coupled to the first data line of the two data line which are adjacent, and the sub pixels in the third row, the fourth row of sub pixels are coupled to the second data line, and the sub pixels in the fifth row, the sixth row of sub pixels are coupled to the first data line.

18. The array substrate according to claim 17, wherein in the first row, the second row, the third row, the fourth row, the fifth row and the sixth row of sub pixels, the sub pixels between two data lines which are adjacent in the second column are the sub pixels of the same type, and the sub pixels in the first row, the second row of sub pixels are coupled to the data line which is close to the first column in the two data lines which are adjacent, and the sub pixels in the third row, the fourth row of sub pixels are coupled to the other data line, and the sub pixels in the fifth row, the sixth row of sub pixels are coupled to the data line which is close to the first column.
